(19) United States
(12) Patent Application Publication
(10) Pub. No.: US 2024/0088185 A1
(43) Pub. Date: Mar. 14, 2024

(54) SENSOR ASSEMBLIES HAVING OPTICAL METASURFACE FILMS

(71) Applicant: 3M INNOVATIVE PROPERTIES COMPANY, St. Paul, MN (US)

(72) Inventors: Martin B. Wolk, Woodbury, MN (US); Craig R. Schardt, Woodbury, MN (US); John A. Wheatley, Stillwater, MN (US); Jonah Shaver, St. Paul, MN (US); Robert L. Brott, Woodbury, MN (US)

(21) Appl. No.: 18/261,380

(22) PCT Filed: Jan. 17, 2022
(86) PCT No.: PCT/IB2022/050351

§ 371 Date: Jul. 13, 2023

Related U.S. Application Data
(60) Provisional application No. 63/147,892, filed on Feb. 10, 2021.

(51) Int. Cl. H01L 27/146; G06V 40/13

(52) U.S. Cl. CPC H01L 27/14627; G06V 40/1318; H01L 27/14621

(57) ABSTRACT

Fingerprint sensor assemblies using metasurface arrays. The sensor assemblies include an image sensor having a sensor pixel array and a metasurface array on the sensor pixel array. An optical filter such as an IR cutfilter or notch filter can be located on the metasurface array. The assemblies can also include a substrate, optical spacer, or optically clear adhesive between the sensor pixel array and the metasurface array. The fingerprint sensor assemblies can be incorporated into mobile devices.

### BACKGROUND

Optical metasurfaces (OMS) are synthetic composite materials comprising arrays of sub-wavelength elements called meta atoms with dimensions on the order of tens or hundreds of nanometers for visible light applications. Optical metasurfaces act locally on an amplitude, phase, or polarization of light, and impart a light phase shift that varies as a function of position on the surface. The metasurfaces may be designed to exhibit properties not readily obtainable using conventional materials and techniques.

Metasurfaces having nano-scale surface features have recently found applications in optics, bio-sensing, semiconductors and other electronic devices. Specific examples include small format near infrared (NIR) cameras for automotive applications, endoscopic camera optics, polarization imaging systems, and dynamic beam steering optics for light detection and ranging (LIDAR).

A system or assembly made up of conventional optical elements (e.g., a compound lens based on refractive lenses) and an OMS can be designed to improve overall optical performance. In these systems, the conventional element provides much of the optical function and the OMS modifies or corrects the system for anomalies, aberrations, or astigmatism.

### SUMMARY

Embodiments of this invention include sensor assemblies having optical metasurface arrays or elements and which can be useful as fingerprint sensors.

### BRIEF DESCRIPTION OF THE DRAWINGS

FIG. 1A is a side view of a microlens array/sensor assembly.

FIG. 1B is a side view of a metasurface array on glass/sensor assembly.

FIG. 1C is a side view of a metasurface array on sensor/film assembly.

FIG. 1D is a side view of a metasurface array on film/sensor assembly.

FIG. 2 is a side view of a multiwavelength, multifocal OMS array used in a sensor assembly to enable image capture and liveness detection.

FIG. 3 is a side view of a metasurface array on sensor assembly.

### DETAILED DESCRIPTION

Described herein are enhanced sensor assemblies for detecting visible and near infrared light. The assemblies comprise a pixelated sensor or a sensor pixel array, an optical film, and at least one optical metasurface array. The combination of these three elements is expected to provide enhanced features and performance for visible and near infrared and ultraviolet (UV) imaging. Potential enhancements include increased signal-to-noise ratio (S/N), hyperspectral imaging capabilities, polarization imaging, liveness detection, and a smaller physical profile. Sensors with these enhancements are useful in consumer electronic devices, for example.

The articles described herein can be useful in a large number of applications including, but not limited to, fingerprint or veinprint sensors capable of sensing both an image and a print location or orientation and fingerprint or veinprint sensor assemblies for visible and near infrared light sources including but not limited to 400-600 nm and 850-940 nm. In particular, the articles and assemblies described herein can be used in the following wavelength ranges: 400 nm-700 nm for visible; 700 nm-2000 nm for NIR; and 100 nm-400 nm for UV.

### Sensor Assemblies 1-3

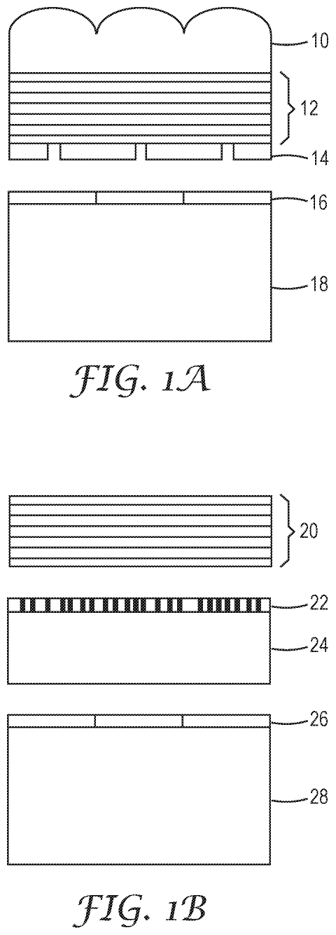

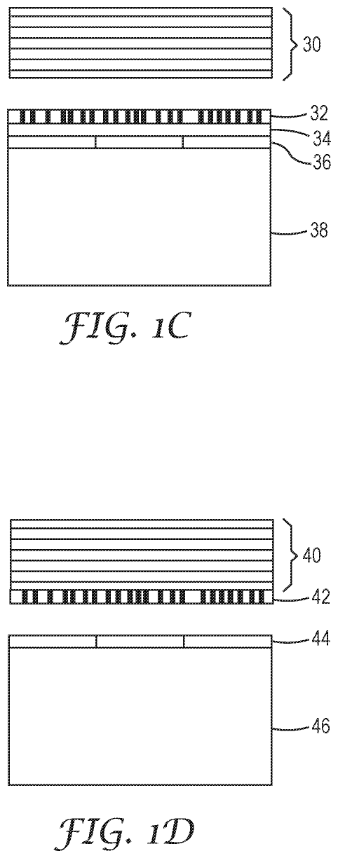

These assemblies are designed and fabricated for a sensor enhancement film as a part of an under-panel fingerprint sensor (FPS) for use in mobile phones or other devices. The film uses optical elements and comprises a refractive microlens array, an infrared (IR) cutoff filter, and an aperture array as an angular filter. Overall, the film serves to collimate and filter light to improve sensor S/N performance (FIG. 1A). The assembly in FIG. 1A includes the following elements arranged as shown: a microlens array 10; an IR cut filter 12; a pinhole array 14; and an image sensor 18 having a pixelated sensor array 16.

Three other assemblies (FIGS. 1B, 1C, 1D) comprise the sensor (CMOS, TFT, or organic photo detector (OPD)), a metasurface array, and an optical film. In each case, the metasurface array is a regular arrangement of individual metalenses with a size and pitch on the order of the corresponding size and pitch of the sensor pixels. The metasurface array is distinct and different from a single, large area metalens disposed adjacent the surface of the sensor. Each metalens in the array may be identical (e.g., in the case of an imaging sensor), or there may be a spatially distributed set of metalens types (e.g., different focal lengths, different spectral range). The metalens array can be aligned on a pixel basis with the underlying sensor pixels or it may be unaligned. The metalens array can be embedded in another material such as an optical resin or other materials. The metalens can be on the order of the size of a pixel or it could be larger covering many pixels or smaller covering a fraction of a pixel. The function of the metalens elements can be to focus light, change the angle of light, polarize light, diffuse light, or to filter light. The filtering function may be spectral, polarization based, angular, or spatial. These functions can be applied to an emitter (or emitter array), a detector (or detector array) or both. Functions can be for imaging or non-imaging applications.

FIG. 1B illustrates one sensor assembly embodiment in which the optical film is a notch filter and the metasurface is disposed on a rigid transparent substrate. The assembly in FIG. 1B includes the following elements arranged as shown: an optical film 20; a metasurface array 22; a rigid transparent substrate 24; and an image sensor 28 having a sensor pixel array 26.

FIG. 1C illustrates a second embodiment in which the metasurface array is disposed on the sensor with an intervening optical spacer layer. The assembly in FIG. 1C includes the following elements arranged as shown: an optical film 30; a metasurface array 32; an optical spacer 34; and an image sensor 38 having a sensor pixel array 36.

FIG. 1D illustrates a third embodiment in which the metasurface is disposed on the optical film. The assembly in FIG. 1D includes the following elements arranged as shown: an optical film 40; a metasurface array 42; and an image sensor 46 having a sensor pixel array 44.

It would be possible to align the sensor array and metalens array in the embodiments of FIGS. 1B, 1C, and 1D.

### Sensor Assembly 4

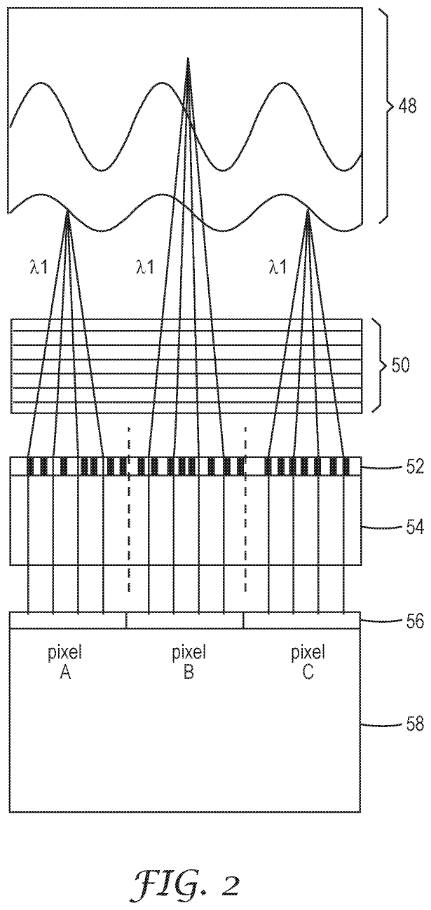

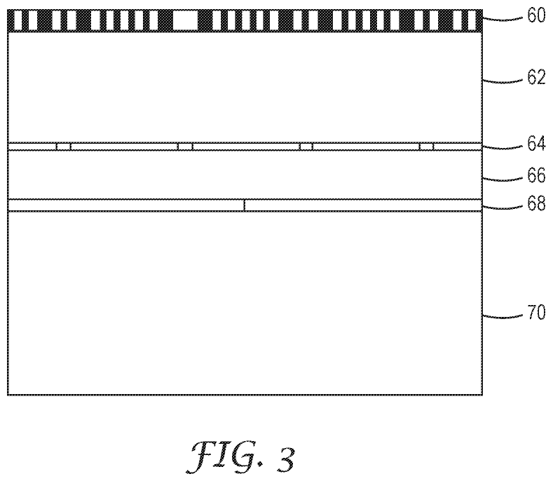

Another sensor assembly embodiment is capable of photoplethysmography (PPG) to enable both security and health sensing or liveness sensing simultaneously during the fingerprint recognition process (FIG. 2). The assembly in FIG. 2 includes the following elements arranged as shown to sense a finger 48: an MOF notch filter 50; a metasurface array 52; a rigid transparent substrate 54; and an image sensor 58 having a sensor pixel array 56.

The system comprises a multiwavelength, multifocal length OMS lens arrays, an image sensor, and a notch filter film. The OMS array is tuned to at least two wavelengths and two focal lengths: a wavelength suitable for imaging the fingerprint surface λ₁ focused on the finger surface (DOF₁) and the optimum wavelength for vein imaging (λ₁, e.g., 850 nm) focused within the first few microns of live tissue (DOF₂). The OMS performs a spatial filtering function, i.e., one metasurface pixel focuses λ1 at f1 and rejects λ2; the other metasurface pixel focuses λ2 at f2 and rejects λ1. And the multi-layer optical film (MOF) allows both λ1 and λ2 to pass.

Optionally, the system can comprise a polarized lens and a polarized source of different polarization states that reduces subcutaneous scatter, enabling entitlement vein imaging in the red or NIR spectral regions.

### Sensor Assembly 5

Another embodiment of a sensor assembly is shown in FIG. 3, in which the metasurface is used without the separate optical film shown in FIGS. 1B, 1C, and 1D. This embodiment can optionally use a dual wavelength metalens in which the focal length of the first wavelength is optimized for pinhole formation and the focal length of the second wavelength is optimized for the optical function. The assembly in FIG. 3 includes the following elements arranged as shown: a metasurface array 60; a transparent substrate 62; a pinhole array 64; an optically clear adhesive (OCA) 66; and an image sensor 70 having a sensor pixel array 68.

In this embodiment (FIG. 3), the metasurface lens array is located on one surface of a transparent substrate which has a second surface that is generally parallel to and spaced a uniform distance, d, apart from the first surface. In a preferred embodiment, the substrate thickness d is chosen so that collimated light incident normal to the metasurface lens array is focused at the second surface of the substrate. An optically opaque coating covers most of the second surface of the transparent substrate except for the locations where normally incident light is focused by the lens array. This coating layer is sometimes referred to as a pinhole array. These openings allow light incident on the lens array from a narrow range of angles, for example ±4° around the normal to pass through the pinhole array toward the detector while blocking light incident on the metasurface from other angles. The coating on the pinhole array is preferably an optically absorbing material to minimize scattering of light inside the film. Examples of suitable coatings include carbon black or roughened and/or blackened metals.

In a preferred embodiment, the metasurface lens array is designed with high chromatic dispersion such that it only focuses a narrow range of wavelengths of light, such as light from 400 nm to 600 nm or light from 800 nm to 1000 nm, through the pinhole array. Light with wavelengths outside of this range is not focused at all or is focused somewhere other than the pinhole array such that it is not efficiently transmitted through the pinhole array to the detector.

The film can be bonded to the detector array by an adhesive such as an optically clear adhesive. The film can also be bonded to the back side of a display module by an optically clear adhesive. The detector array or display module can comprise a planar substrate or a curved substrate. One advantage of the metasurface array approach over a microlens array is that it can be made with a flat top surface that is amenable to direct optical bonding.

A metasurface element, such as the one described herein, serves as both an angular and a spectral filter for a large-area fingerprint sensor. The spectral filtering can further be increased by adding dyes or pigments that absorb undesired wavelengths of light to the transparent substrate and/or to the adhesive layers used to bond it to the detector and/or display module.

The assemblies described herein can be used as fingerprint sensors when a finger is placed directly on (in physical contact with) or in sufficient proximity to the top-most component of the assemblies opposite the image sensors.

1-10. (canceled)

11. A sensor assembly, comprising:
a sensor pixel array;
a metasurface array on the sensor pixel array; and
an IR cut filter on a side of the metasurface array opposite the sensor pixel array.

12. The assembly of claim 11, wherein the metasurface array comprises metalenses having a size and a pitch on the order of a corresponding size and pitch of the sensor pixel array.

13. The assembly of claim 11, wherein the metasurface array comprises metalenses each covering a plurality of pixels in the sensor pixel array.

14. A sensor assembly, comprising:
a sensor pixel array;
a transparent substrate on the sensor pixel array;
a metasurface array on a side of the substrate opposite the sensor pixel array; and
a notch filter on a side of the metasurface array opposite the substrate.

15. The assembly of claim 14, wherein the metasurface array comprises metalenses having a size and a pitch on the order of a corresponding size and pitch of the sensor pixel array.

16. The assembly of claim 14, wherein the metasurface array comprises metalenses each covering a plurality of pixels in the sensor pixel array.

17. The assembly of claim 14, wherein the metasurface array comprises a plurality of metalenses covering an individual pixel in the sensor pixel array.

18. The assembly of claim 14, wherein the metasurface array is tuned to at least two wavelengths and at least two focal lengths.

19. (canceled)

20. The assembly of claim 14, wherein the notch filter is polarization selective.

21. The assembly of claim 14, wherein the metasurface array is polarization selective.

22. A sensor assembly, comprising:
a sensor pixel array;
an optically clear adhesive on the sensor pixel array;
a pinhole array on a side of the optically clear adhesive opposite the sensor pixel array;
a transparent substrate on a side of the pinhole array opposite the optically clear adhesive; and
a metasurface array on a side of the substrate opposite the pinhole array.

23. The assembly of claim 22, wherein the metasurface array comprises metalenses having a size and a pitch on the order of a corresponding size and pitch of the sensor pixel array.

24. The assembly of claim 22, wherein the metasurface array comprises metalenses each covering a plurality of pixels in the sensor pixel array.

25. The assembly of claim 22, wherein the metasurface array comprises a plurality of metalenses covering an individual pixel in the sensor pixel array.

26. The assembly of claim 22, wherein the pinhole array comprises an optically absorbing material.

27. The assembly of claim 22, further comprising a dye or a pigment on the substrate or on the optically clear adhesive.

28. The assembly of claim 22, further comprising a spatial or angular filtering function.

29. A mobile device having an imaging sensor to image a user body portion placed proximate to the device, comprising the sensor assembly of claim 11.

30. (canceled)

31. The sensor assembly of claim 11, further comprising a transparent substrate on the sensor pixel array opposite the metasurface array.

32. The sensor assembly of claim 11, further comprising an optical spacer on the sensor pixel array opposite the metasurface array.
